(19) United States
(12) Patent Application Publication
(10) Pub. No.: US 2026/0177609 A1
(43) Pub. Date: Jun. 25, 2026

(54) SEMICONDUCTOR AGE MONITORING

(71) Applicant: Intel Corporation, Santa Clara, CA (US)

(72) Inventors: Maxim LEVIT, Binyamina (IL); Eran ALTSHULER, Kiriat Ata (IL)

(21) Appl. No.: 19/000,757

(22) Filed: Dec. 24, 2024

(51) Int. Cl. G01R 31/28

(52) U.S. Cl. CPC G01R 31/2884

(57) ABSTRACT

Aging monitor circuits are provided that compare aged oscillator frequencies against fresh oscillator frequencies to determine an aging value. Also provided are supply voltage adjustment circuits that can use first and second oscillators to identify an amount of supply voltage adjustment needed to maintain transistor performance levels.

### BACKGROUND

Aging of modern electronic and semiconductor devices imposes significant risk for device reliable functioning during projected service life. Having a reliable aging sensor is needed for preventing device malfunctioning and for alarming users before malfunctions can happen.

There are various different existing age monitoring solutions. So called digital aging sensors (DAS) use complicated approaches for measuring differences in delay for stressed and unstressed identical timing paths and translating the differences into voltage degradation. A disadvantage of these DAS approaches is their complexity, need for a relatively large number of fuses, calibration procedures, manufacturing and validation enablement efforts and accuracy related to temperature. Another approach counts the amount of time critical circuits are under stress by capturing and accumulating their durations in high stress situations, e.g., higher voltage/frequency modes, and translating such durations into voltage degradation levels through predefined formulas. However, such methods typically require non-volatile memory to store accumulated stress information. Another disadvantage is their dependence on predefined correlation formula s, which is based on worst case units instead of per unit, resulting in accuracy issues.

### BRIEF DESCRIPTION OF THE DRAWINGS

The disclosure may best be understood by referring to the following description and accompanying drawings that are used to illustrate embodiments. In the drawings:

FIG. 1 is a block diagram showing a processor with aging monitor circuits in accordance with some embodiments.

FIG. 2 is a block diagram showing aging monitor circuits in accordance with some embodiments.

FIG. 3 is a hybrid flow diagram showing an aging monitoring routine in accordance with some embodiments.

FIG. 4 is a block diagram showing an aging monitor circuit for monitoring a circuit group in accordance with some embodiments.

FIG. 5 is a flow diagram showing another routine for monitoring aging in accordance with some embodiments.

FIG. 6A is a block diagram showing a dynamic voltage adjustment circuit for adjusting a supply voltage for a monitored circuit in accordance with some embodiments.

FIG. 6B is a flow diagram showing a routine for dynamically adjusting a supply voltage in accordance with some embodiments.

FIG. 7A is a graph illustrating a voltage needed to maintain operational performance in accordance with some embodiments.

FIG. 7B is a graph illustrating the relationship between a circuit's operating frequency and the voltage needed to achieve the frequency over time as the circuit ages in accordance with some embodiments.

FIG. 8 illustrates an example computing system including one or more age monitor and/or voltage adjustment circuits in accordance with some embodiments.

FIG. 9 illustrates a block diagram of an example processor and/or SoC 900 that may have one or more cores and an integrated memory controller and may include age monitor and/or voltage adjustment circuits in accordance with some embodiments.

FIG. 10 is a block diagram illustrating a computing system 1000 configured to implement one or more aspects of the examples described herein.

### DETAILED DESCRIPTION

In addition to allowing for tighter supply voltage guardbands, efficient, accurate aging monitor circuits can also be used to prevent counterfeiting (e.g., to identify older chips passed off as new chips), as well as for other purposes.

In some embodiments, aging monitor circuits are provided that are reasonably temperature and voltage independent, are accurate, and are relatively convenient to implement.

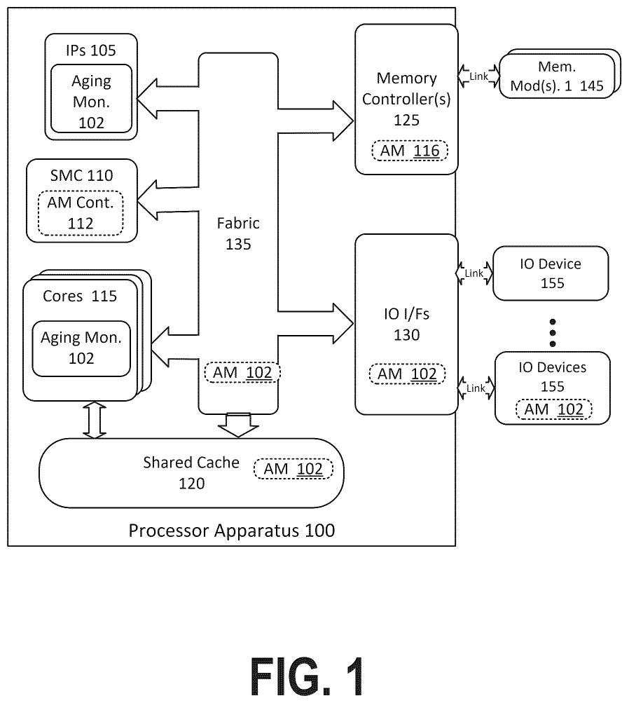

FIG. 1 is a block diagram showing aging monitor circuits 102 in accordance with some embodiments. The processor 100 includes IP (intellectual property) circuits 105, a system management controller (SMC) 110, processing cores 115, shared cash circuitry 120, a memory controller 125, IO interface circuits 130, and system fabric 135, all coupled together as shown. Also included are memory modules 145 coupled to the memory controller(s) 125 through memory channels. Similarly, IO devices 155 coupled to the I/O interface circuits 150 through IO interface channels are also included.

The processor apparatus 100 comprises at least one hardware circuit configured to execute instructions (e.g., in processor cores 115) contained in program code. The hardware circuit may be implemented with one or more integrated circuits. Examples of processor types that may be implemented in processor 100 include, but are not limited to, central processing units (CPU), array processors, vector processors, digital signal processors (DSP), field-programmable gate arrays (FPGA), application specific integrated circuits (ASIC), graphics processing units (GPU), artificial intelligence processing units (AIPU), and so forth. It should be appreciated that the processor 100 may be implemented in various different manners. For example, it may be implemented on a single die, multiple dies (dielets, chiplets), one or more dies in a common package, or one or more dies in multiple packages. Along these lines, some of the depicted blocks may be located separately on different dies or together on two or more different dies.

The IP circuits 105 are circuits that perform a particular function. An IP circuit (or IP) may be a unit of logic, circuit, cell, or chip layout that is reusable. A few examples of IP circuits include processor cores, memories, caches, floating point processors, memory controllers, bus controllers, graphics processors, transceivers, network interface controllers, and display controllers. One or more portions of a larger IP can themselves be designated as IP circuits. For example, an instruction execution unit and cache controller may be IP for a processor IP. In some embodiments, one or more IP blocks may include aging monitor circuits 102 (including age determination and/or dynamic supply voltage adjustment), as will be described below, to monitor and in some cases respond to transistor aging in the one or more IP blocks.

The SMC 110 includes one or more microcontrollers, state machines and/or other logic circuits for controlling various aspects of the processor 100. For example, it may manage functions such as security, boot configuration, and power and performance including utilized and allocated power along with thermal management. The SMC may also be referred to as a P-unit, a power management unit (PMU), a power control unit (PCU), a system management unit (SMU) and the like and may include multiple SMCs, PMUs, die management controllers, etc.

In some embodiments, the SMC 110 includes aging monitor control logic to control, oversee, and/or act in response to data from the aging monitor circuits 102. The aging monitor control logic 112 may be implemented with the SMC running code (e.g., firmware), or it may be implemented wholly or partially with dedicated control logic circuitry such as a micro-controller or finite state machine (FSM), or with any other suitable combination of hardware and/or executing code.

The processing cores 115 comprise cores for executing code in accordance with desired functionality for the processor 100. They may comprise any suitable combination of core types such as compute (e.g., CPU) cores, graphics cores, parallel processing cores, vector processing cores, and the like, and may be implemented with differently sized core instances and/or by using the same or different instruction set architectures. Specific implementations will depend on functionality, as well as power and performance objectives. One or more of the cores 115 may include aging monitor circuits 102 for monitoring aging, circuit degradation, and/or dynamic voltage adjustment in the cores. In some embodiments, they may also or alternatively be used for adjusting voltage levels used for powering the cores, e.g., on a core by core or even finer partition level basis. The other blocks of the processor 100 may also include aging monitor circuits 102, as is indicated in the figure. Examples of aging monitor circuits are presented below.

The shared cache 120 includes one or more levels of cache memory, typically random access memory (RAM) that is used by the other blocks in the processor including the processor cores 115. Some or all of it may be part of an overall memory system that also includes the memory modules 145. The IO devices 155 and their associated IO interfaces 130 are coupled with the Processor 100 to provide additional functionality and/or better performance capabilities. For example, they may include IO interface devices such as PCIe (Peripheral chip Interconnect express), USB (Universal Serial Bus) and/or CXL (Compute Express Link) interfaces for peripheral user interface devices, displays, accelerators, graphics cards, and the like.

The memory controller(s) 125 is coupled to the memory modules 145. The memory modules are typically made up of DRAM memory chips, and each module may include a power delivery circuit and a memory module controller to interface between the raw memory and the memory controller 125. The memory may be implemented using any suitable type such as DDR double data rate), LPDDR (Low Power DDR), and the like. Accordingly, the channels that make up the memory channels operate in conformance with whatever memory type is being implemented.

The fabric 135 is a communications network of interconnected nodes to couple to one another the various different blocks of the processor 100. In some embodiments, it facilitates high-speed data transfer and communication, which allows for the creation of unified computing systems where the different components can work together. For convenience, a single overall fabric is shown, but fabric 135 may comprise multiple different fabrics and interconnection structures such as mesh and ring networks, as well as busses and point-to-point connections. In some embodiments, it may include separate different fabrics, e.g., a main data fabric for transferring data between the blocks and a control fabric for setting parameters, reading operational states, managing operating modes, communicating telemetry, and the like. Communications for controlling and/or reading from the aging monitor circuits 102 may be carried out with one or more interconnects in fabric 135 or through other communication links within the processor.

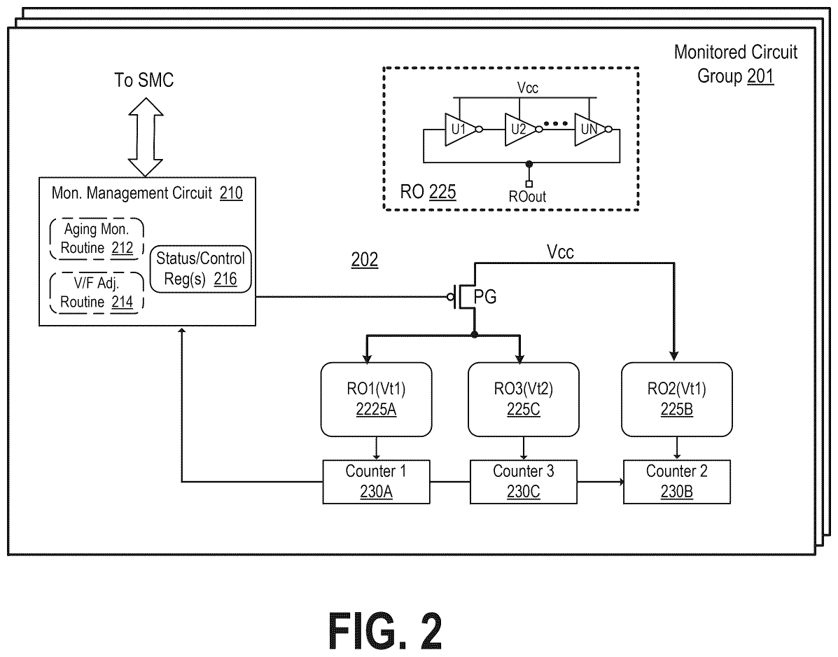

FIG. 2 is a block diagram showing a processor with aging monitor circuits 202 in accordance with some embodiments. The aging monitor (AM) circuits 202 may be used for AM circuit 102 and/or distributed in a variety of different circuit groups 201 such as cores, IP blocks, etc., that are to be monitored. In some embodiments, there is at least one aging monitor circuit 202 in each core of a processor and in some cases, depending on the core size and architecture, there may be multiple AM circuits.

One or more of the circuits 202 include a monitor management (or simply management) circuit 210, a power gate (PG) switch, a first ring oscillator (RO1) 225A, a second ring oscillator (RO2) 225B, a third ring oscillator (RO3) 225C, and associated counters (230A-230C) coupled together as shown. RO1 and RO2 are used to determine aging of the monitored circuit group 201, while RO1 and RO3 are used to identify temperature (T), and in some cases voltage (V), for the aging determination. As such, RO1 and RO3 are kept “fresh”, i.e., they are powered when used for aging and/or temperature determinations are being made and otherwise kept powered off. On the other hand, RO2 is allowed to age with the circuits being monitored. Accordingly, RO1 and RO3 are coupled to the monitored circuit group's supply voltage (Vcc) through the power gate (PG), which is controlled by management circuit 210, while oscillator RO2 is coupled with the circuits being monitored to the supply voltage (Vcc). (The supply voltage (Vcc) is a supply used to power circuits within a partition (e.g., core, IP, etc.) that are to be monitored. RO2 is to be operated in concert with these circuits. So, while it is shown connected directly to Vcc, it should be understood that it may be connected to any rail, power gate or other virtual supply that may also be used for powering the circuits being monitored. That is, in some embodiments, it will be subjected to the same conditions as the monitored circuits. Along these lines, the RO circuits themselves should be made using the same processes as the circuits being monitored and should also be located sufficiently near or even within them.)

An exemplary ring oscillator circuit 225 is shown in the dashed box. It includes N inverters (e.g., P/N MOS inverters) coupled together as shown in a ring oscillator configuration (e.g., with an odd number of inverter stages). (As used herein, a P/N inverter is an inverter formed from a P-type transistor and an N-type transistor with their gates coupled to one another and their drains also coupled to one another.) In some embodiments, a relatively large number, e.g., 21 or more, separate inverters may be used for the ring oscillators to provide a larger sample size so as to better average out significant inverter deviations from designed-for parameters. (Note that while ring oscillator circuits are shown, any suitable oscillator design may be used, so long as the aging of its transistors can be monitored in accordance with the techniques described herein.)

The monitor management circuit 210 manages operations of the ring oscillators for determining aging of the monitored circuit(s). It may be implemented with any suitable circuit such as with a micro-controller, state machine(s), combinations thereof, or even by other controllers such as a central monitor management control circuit, an SMC, or wholly and/or in combination with software such as control code, drivers or BIOS software running in the processor.

The depicted management circuit 210 includes logic for implementing an aging monitoring routine 212 and/or logic for implementing a V/F (voltage/frequency) adjustment routine 214. The management circuit 210 also includes memory including status/control registers 216 to store various different parameters such as aging values, operations control information and the like. The management circuit may also include tables and/or arithmetic information corresponding to modeled or tested voltage, temperature and aging parameters for the circuit(s) being monitored in order to use them to determine aging information for the circuits using the ring oscillators. These tables and/or arithmetic information may alternatively be stored outside of the aging monitor, e.g., in a central management control logic 112 or elsewhere.

In some embodiments, the oscillators are implemented with the same circuit configurations except that the first and second oscillators (RO1, RO2) use transistors with the same voltage thresholds (Vt1), while the third oscillator (RO3) uses transistors with a different threshold (Vt2). Since the different thresholds are used to determine temperature, in some embodiments, the Vt1, Vt2 thresholds may be selected using the widest available separation as is available.

In operation, the first and third ring oscillators, RO1(Vt1), RO3(Vt2, are used to determine instant voltage and temperature. This may be done by generating look-up tables and/or curves through pre-characterization and simulation of the ring oscillators. Using similar approaches, RO1 and RO2 are used to determine an aging value. For either measurement, the frequencies of the oscillators are measured using counters 230. When frequency measurements are to be made, the management circuit controls the counters to reset, start counting and then stop counting after a known, set amount of time. The faster oscillators (less aged or with lower Vt) will have higher counts. From here, the frequencies may be determined or the counts themselves may be used without conversion to actual frequencies.

Since RO1 and RO3 have different voltage thresholds but are otherwise the same, they may be used to determine temperature and voltage through substantially (or effectively) simultaneous reading of their frequencies and extracting their temperature and voltage from look-up/arithmetic models that have been generated using the following two linear relationships:

$$\begin{matrix}F 1 = a V + bT ( 1 ) \\ F 3 = c V + dT ( 1 )\end{matrix}$$

where F1 is the frequency of RO1, F3 is the frequency of RO3, V is the voltage applied to each of the oscillators and T is their temperature. The coefficients: a, b, c, and d may be determined through testing, modeling, and/or simulation of the oscillators across various different operating points. This may be done during pre-silicon simulation and/or post silicon characterization and calibration. The generated data may then be stored in a look-up table or fitted into a formula from which V and T or even just T may be determined based on measured values of F1 and F3. (Note that in some embodiments, the oscillator voltages may be identified from the known applied value of Vcc but in other embodiments, it may be more accurate to derive a precise voltage value from the frequency measurements and generated oscillator F/V/T relationships.)

RO1 and RO2 may then be used to determine an aging value, e.g., a an aging time, as say normalized against an expected aging time in terms of actual degradation.

Again, RO1 and RO2 are made the same in terms of transistor type and layout and are located close to each other. The difference between them is that RO1 is fresh, not normally connected to power, while RO2 is aged, continually connected to the power supply along with the circuits its monitoring.

A similar approach as just described for determining V and T from RO1 and RO3 may also be used for an aging determination except that the mathematical relationships are different. For aging, comparing the aging of an actual circuit/transistor type against its expected normal aging, the effective aging behaves as follows:

$${Age}_{y e a r s} = {e}^{A [ T , V ]} \times {Degradation}^{B [ T ]}$$

where A(T, V) is a 2nd degree polynomic estimate by voltage, and the A, B polynomic parameters are linear estimates of temperature using fixed coefficient values derived from modeling the circuits across an array of operating points and temperatures. F1 is the frequency of RO1, F2 is the frequency of RO2, and degradation is: (F1−F2)/F1. Thus, it can be seen that an estimate of the number of years of degradation under specific stress and silicon sensitivity can be generated from RO frequency degradation at a given voltage and temperature. It might be that different stresses and materials will give the same effect, but this value can at least be used as a reference. Note that in some embodiments, circuits other than oscillators may be used to measure delay, which can be applied as a reciprocal of frequency.

Through pre-silicon modeling and/or simulations and/or post silicon characterization and/or calibration, this relationship between voltage, temperature and RO frequencies for an aged versus a fresh test oscillator of the same type may be used to generate a look-up table and/or formulas to be later used with an operational AM circuit to determine the effective aging of its monitored circuit.

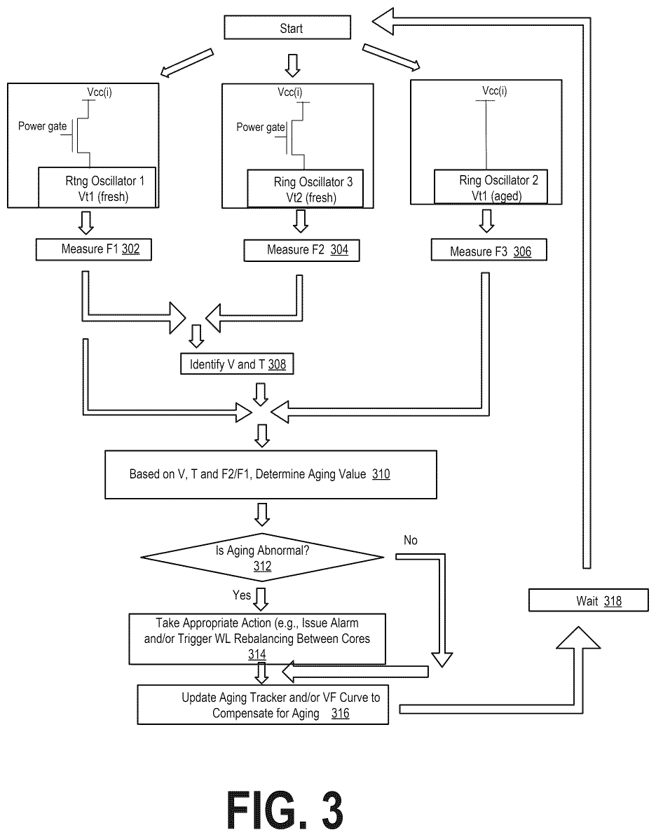

FIG. 3 is a hybrid flow diagram showing an aging monitoring routine in accordance with some embodiments. For example, this routine may be used with the circuit of FIG. 2. In some embodiments, this routine for determining an effective aging value may be performed in response to a specific request, e.g., from the OS, BIOS or a security agent, or it may be performed on a regular cadence, e.g., from once an hour to once a day. The results may then be stored either in the management circuit or elsewhere in a more centralized location. The aging value may be stored in non-volatile memory, although this is not necessary since it can be determined a new at any desired time.

When an aging determination is to be made, power to RO1 and RO3 is switched on so that all three oscillators are running from here, at 302, 304, and 306, the frequencies of RO1, RO2, and RO3 are together measured. AT 308, the voltage and temperature are identified, e.g., using a technique as described above. Next, at 310, the effective aging value is determined using T, V and the F2/F1 ratio. Once the parameters needed to determine the aging value have been identified, power is removed from RO1 and RO3 so as to preserve them in their fresh states as well as can reasonably be achieved.

At 312, the routine checks if the determined age value is abnormal, e.g., problematic or otherwise actionable. If so, then at 314, it takes action such as triggering an alarm or moving work from the circuit (e.g., core) to another circuit block with less aging. Finally, at 316, it updates voltage levels for frequency operating points (i.e., a V/F curve for the monitored circuit in question) based on the new age value. If at 312, it was determined that the aging was normal or at least not otherwise problematic, then it would proceed directly to block 316. From here, it proceeds to 318, essentially awaiting for the next aging determination event to occur.

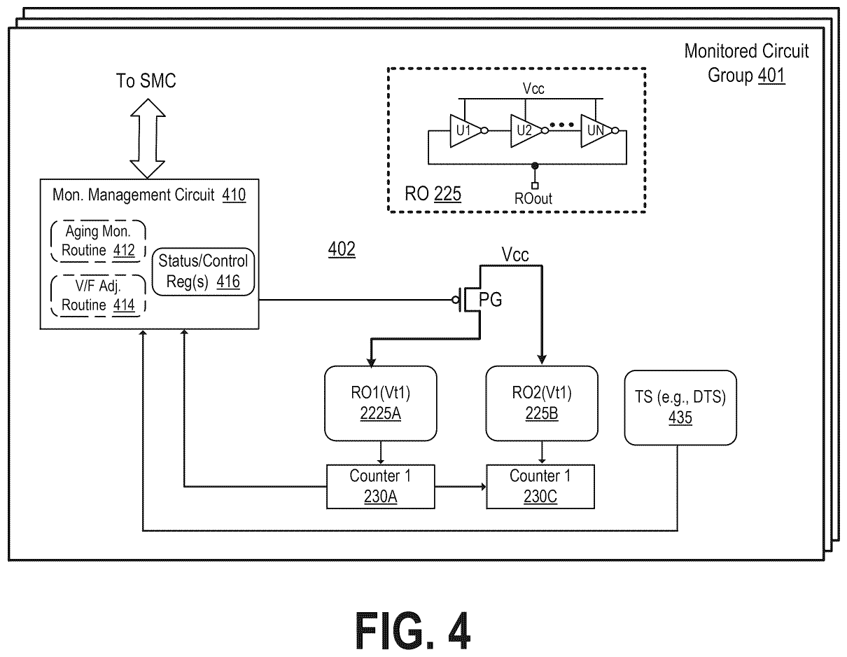

FIG. 4 is a block diagram showing an aging monitor circuit 402 for monitoring a circuit 401 in accordance with some embodiments. This circuit is similar to the circuit of FIG. 2 except that it uses a separate temperature sensor 435 instead of two oscillators for measuring temperature. Thus, only two oscillators, RO1 and RO2, are needed for this aging determination. Any suitable temperature sensor circuit such as a digital temperature sensor (DTS) may be used for temperature sensor 435.

With this aging monitor circuit, the fresh oscillator (RO1) may be used to extract voltage, as described above, using the known temperature from temperature sensor 435 and the frequency of RO1. And, by knowing temperature and voltage, the fresh frequency and the “aged” frequency from the fresh RO1 and aged RO2 may be used to determine an aging value. The embodiment of FIG. 2 may be preferred in some applications where a self-contained aging sensor is desired, i.e., without the need for an available temperature sensor. On the other hand, where temperature circuits are conveniently available, the embodiment of FIG. 4 may be preferred.

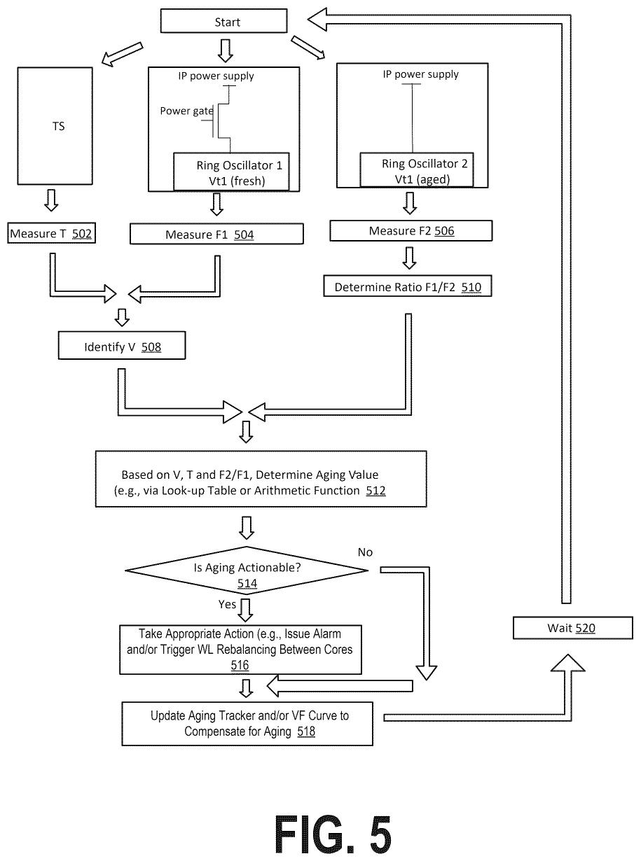

FIG. 5 is a flow diagram showing another routine for monitoring aging in accordance with some embodiments. This routine is similar to the routine of FIG. 3 except that the temperature is derived from temperature sensor 435 instead of relying upon a third oscillator. In some embodiments, this routine for determining an effective aging value may be performed in response to a specific request, e.g., from the OS, BIOS or a security agent, or it may be performed on a regular cadence, e.g., from once an hour to once a day. The results may then be stored either in the management circuit or elsewhere, for example, in a more centralized location. The aging value may be stored in non-volatile memory, although this is not necessary since it can be determined a new at any desired time.

When an aging determination is to be made, power to RO1 is switched on so that RO1 and RO2 are running from here, at 502, the temperature is identified from temperature sensor 435, and at 504 and 506, the frequencies of RO1 and RO2, F1 and F2 respectively, are together measured, and their ratio is identified at 510. AT 508, the voltage is identified, e.g., using a technique as described above by extracting from RO1 with knowledge of the temperature or simply by knowing the programmed supply voltage.

Next, at 512, the effective aging value is determined using T, V and the F2/F1 (or F1/F2) ratio. Once the parameters needed to determine the aging value have been identified, power is removed from RO1 so as to preserve them in their fresh states as well as can reasonably be achieved.

At 514, the routine checks if the determined age value is abnormal, e.g., problematic or otherwise actionable. If so, then at 516, it takes action such as triggering an alarm or moving work from the circuit (e.g., core) to another circuit block with less aging. Finally, at 518, it updates voltage levels for frequency operating points (i.e., a V/F curve for the monitored circuit in question) based on the new age value. If at 312, it was determined that the aging was normal or at least not otherwise problematic, then it would proceed directly to block 316. From here, it proceeds to 520, essentially awaiting for the next aging determination event to occur.

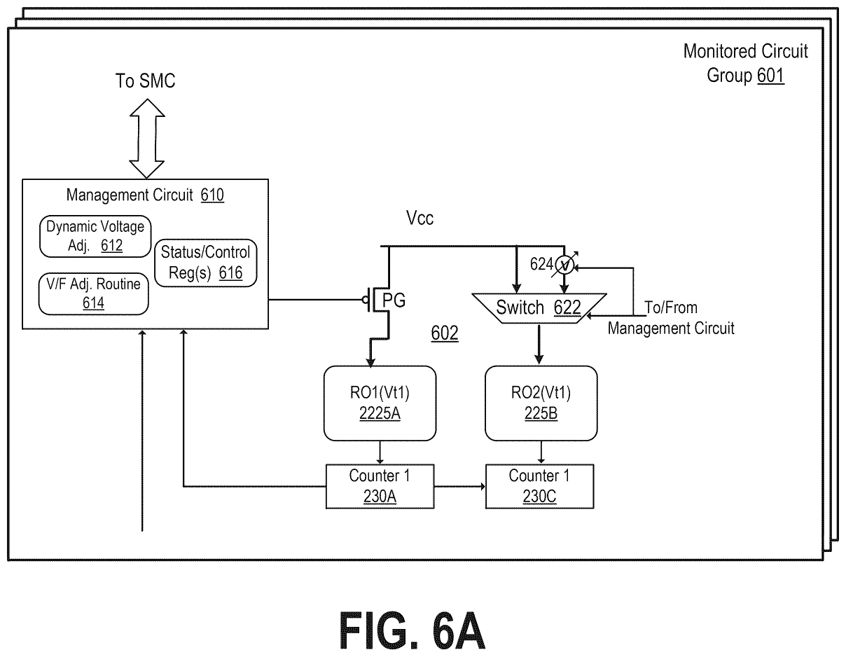

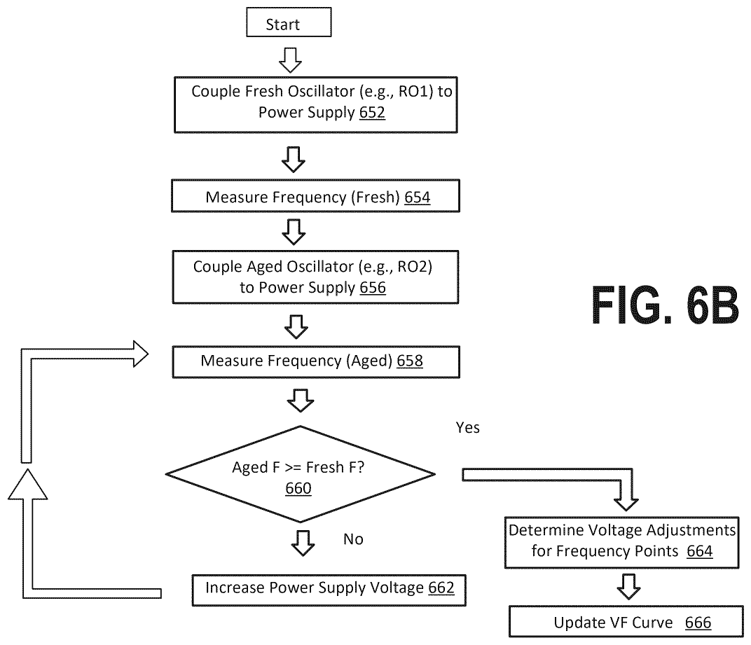

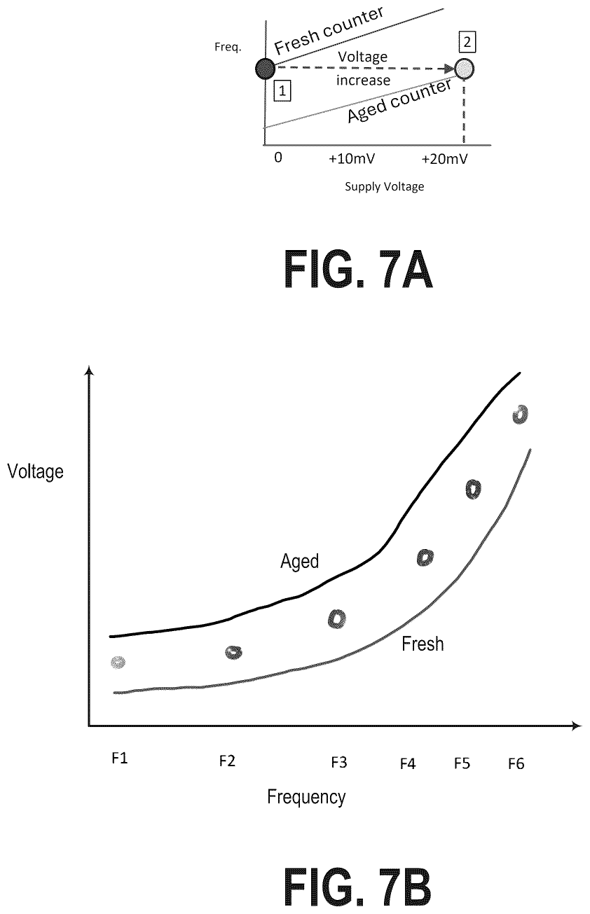

With reference to FIGS. 6A, 6B, 7A, and 7B, a solution for dynamically updating a processor supply voltage based on aging in accordance with some embodiments will now be described. FIG. 6A is a block diagram showing a dynamic voltage adjustment circuit 602 for adjusting a supply voltage for a monitored circuit 601 in accordance with some embodiments. FIG. 6B is a flow diagram showing a routine for dynamically adjusting a supply voltage. FIG. 7A is a graph illustrating a voltage needed to maintain operational performance, and FIG. 7B is a graph illustrating the relationship between a circuit's operating frequency and the voltage needed to achieve the frequency over time as the circuit ages.

Digital CMOS (complementary metal oxide semiconductor) logic typically works at high voltages and temperatures to gain performance, but long durations under these conditions alter transistor parameters, causing speed degradation. That speed degradation eventually can cause unit functional failures if it is not compensated with a suitable voltage increase.

Specific speed degradation for a given circuit is dependent on voltage and temperature and is different from die to die, depending on operational conditions (e.g., workloads, voltage wave forms, durations, etc.). With conventional platforms, a traditional way to prevent unit malfunction due to speed degradation is to apply flat over-voltages (voltage guard band) to compensate for the expected speed degradation at product End of Life. However, applying worse-case over-voltage guardbands invariably results in higher power, lower performance and higher degradation.

Accordingly, in some embodiments, new approaches are provided. In some embodiments, for example, speed degradation need not be measured but at the same time, the voltage maybe gradually raised over time based on measured performance to maintain the circuit at a reasonably fresh operational state. In some embodiments, fresh and aged ring oscillators (e.g., RO1, RO2 from 202 or 402) are used without the need for stored parameters (e.g., in fuses or the like).

It has been observed that although speed degradation highly depends on the temperature and voltage, the voltage shift causing speed recovery mainly depends on the voltage. This observation allows for solutions where temperature, or temperature control, may be neglected. Avoiding high voltage guard-bands from the start can benefit both in power waste and can reduce stress at high voltages, enabling longer times where the guard band is not needed.

With reference to FIG. 6A, the dynamic voltage adjustment circuit is similar with the monitor circuits of FIGS. 2 and 4 except that it need not include a circuit to measure temperature, but it does include circuitry for the management circuit 610 to switch the aged oscillator (RO2) between the monitored circuit supply (Vcc) and a controllable voltage supply 624. A multiplexer type switch 622 is used for this purpose. Normally, the aged oscillator (RO2) is powered by the Vcc supply, as with the aged oscillators of FIGS. 2 and 4, but when a voltage adjustment is to occur, the supply is switched to the controllable voltage 624.

The voltage adjustment routine of FIG. 6B will now be presented. At 652, the fresh oscillator (e.g., RO1) is coupled to the power supply Vcc, the power supply for the circuit being monitored. At 654, the frequency (F1) of the fresh oscillator (RO1) is measured, e.g., cycles counted over a known time interval. At 656. the aged oscillator (e.g., RO2) is coupled to the controllable supply voltage. At 658, the frequency (F2) of the aged oscillator (RO2) is measured (e.g., counted) over the period of time. Note that while these steps are presented as distinct, separate sequential steps, in some embodiments, as with some of the methods of FIGS. 3 and 5, the frequencies (F1, F2) may be measured together, e.g., with a management circuit applying a common enable/disable signal to the counters for both oscillators in tandem.

AT 660, the routine determines if the aged frequency (F2) is greater or equal to that of the fresh oscillator (RO1). If not, then at 662, it increases the controllable Supply Voltage and loops back to 658. For example, it may increase the voltage using relatively small increments such as 5 to 10 mV increments. It continues through this loop until at 660, it is determined that F2 is greater or equal to F1. Once this occurs, the routine proceeds to 614 and identifies and/or stores the amount of voltage increase that was needed to get to this point (i.e., where F2 became greater or equal to F1). Then, at 616, the routine updates relevant VF Curves.

It's worth noting that voltage regulators can cause ripple in supply voltages that may alter oscillator speed for short times. A way to address this is to enable long enough frequency count durations to overcome ripple impacts and local droops caused by sudden current increase. Along these lines, for each frequency determination, multiple measurements may be made and then averaged or at least confirmed to be consistent with one another.

In addition, the measurement of the fresh oscillator and the aged oscillator may be performed and/or compared at different times and therefore may suffer from load changes during test times because voltage is set on VR while a varying load during test can alter the actual voltage, e.g., due to IR drops on oscillators between the fresh and aged oscillator tests at different voltages, which are also at different times. A way to address this issue is to guarantee no load change during test by performing measurements at forced idle times such as with idle C-states or at a reset. Forcing idle modes for testing may also be done if the up time is high (without a state change). Another way may be to allow testing during normal operation but repeat reference and test several times raising and lowering the controllable voltage to get consistent results to verify that average load has not been changed during the voltage shift.

Another issue is oscillator variation. Variations between the oscillators can cause false aging measurements and could cause a late adjustment when the fresh oscillator is slower than the aged one from the start.

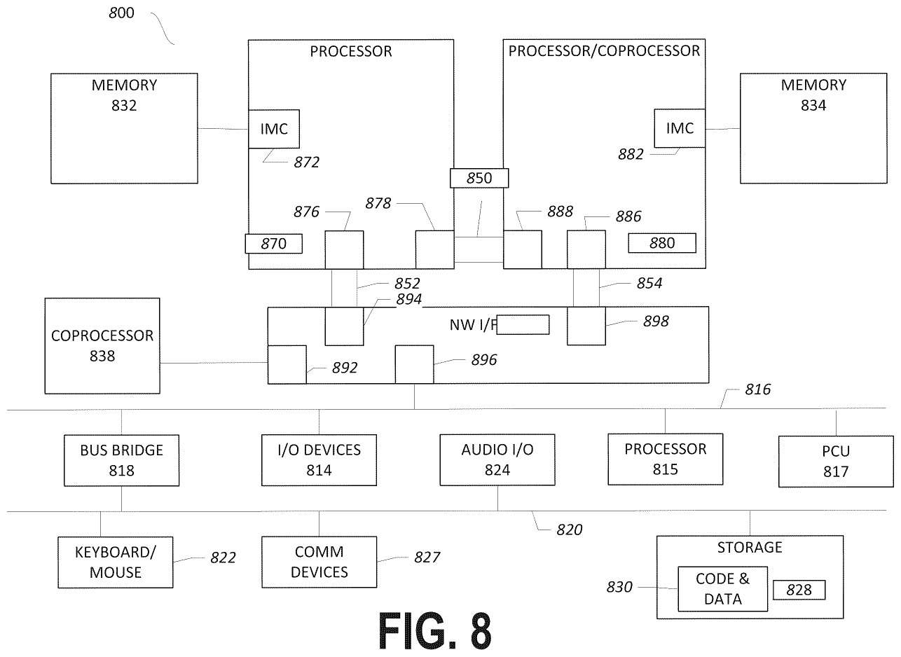

FIG. 8 illustrates an example computing system including one or more age monitor and/or voltage adjustment circuits in accordance with some embodiments. Multiprocessor system 800 is an interfaced system and includes a plurality of processors including a first processor 870 and a second processor 880 coupled via an interface 850 such as a point-to-point (P-P) interconnect, a fabric, and/or bus. In some examples, the first processor 870 and the second processor 880 are homogeneous. In some examples, first processor 870 and the second processor 880 are heterogenous. Though the example system 800 is shown to have two processors, the system may have three or more processors, or may be a single processor system. In some examples, the computing system is implemented, wholly or partially, with a system on a chip (SoC) or a multi-chip (or multi-chiplet) module, in the same or in different package combinations.

Processors 870 and 880 are shown including integrated memory controller (IMC) circuitry 872 and 882, respectively. Processor 870 also includes interface circuits 876 and 878, along with core sets. Similarly, second processor 880 includes interface circuits 886 and 888, along with a core set as well. A core set generally refers to one or more compute cores that may or may not be grouped into different clusters, hierarchal groups, or groups of common core types. Cores may be configured differently for performing different functions and/or instructions at different performance and/or power levels. The processors may also include other blocks such as memory and other processing unit engines.

Processors 870, 880 may exchange information via the interface 850 using interface circuits 878, 888. IMCs 872 and 882 couple the processors 870, 880 to respective memories, namely a memory 832 and a memory 834, which may be portions of main memory locally attached to the respective processors.

Processors 870, 880 may each exchange information with a network interface (NW I/F) 890 via individual interfaces 852, 854 using interface circuits 876, 894, 886, 898. The network interface 890 (e.g., one or more of an interconnect, bus, and/or fabric, and in some examples is a chipset) may optionally exchange information with a coprocessor 838 via an interface circuit 892. In some examples, the coprocessor 838 is a special-purpose processor, such as, for example, a high-throughput processor, a network or communication processor, compression engine, graphics processor, general purpose graphics processing unit (GPGPU), neural-network processing unit (NPU), embedded processor, or the like.

A shared cache (not shown) may be included in either processor 870, 880 or outside of both processors, yet connected with the processors via an interface such as P-P interconnect, such that either or both processors' local cache information may be stored in the shared cache if a processor is placed into a low power mode.

Network interface 890 may be coupled to a first interface 816 via interface circuit 896. In some examples, first interface 816 may be an interface such as a Peripheral Component Interconnect (PCI) interconnect, a PCI Express interconnect, or another I/O interconnect. In some examples, first interface 816 is coupled to a power control unit (PCU) 817, which may include circuitry, software, and/or firmware to perform power management operations with regard to the processors 870, 880 and/or co-processor 838. PCU 817 provides control information to one or more voltage regulators (not shown) to cause the voltage regulator(s) to generate the appropriate regulated voltage(s). PCU 817 also provides control information to control the operating voltage generated. In various examples, PCU 817 may include a variety of power management logic units (circuitry) to perform hardware-based power management. Such power management may be wholly processor controlled (e.g., by various processor hardware, and which may be triggered by workload and/or power, thermal or other processor constraints) and/or the power management may be performed responsive to external sources (such as a platform or power management source or system software).

PCU 817 is illustrated as being present as logic separate from the processor 870 and/or processor 880. In other cases, PCU 817 may execute on a given one or more of cores (not shown) of processor 870 or 880. In some cases, PCU 817 may be implemented as a microcontroller (dedicated or general-purpose) or other control logic configured to execute its own dedicated power management code, sometimes referred to as P-code. In yet other examples, power management operations to be performed by PCU 817 may be implemented externally to a processor, such as by way of a separate power management integrated circuit (PMIC) or another component external to the processor. In yet other examples, power management operations to be performed by PCU 817 may be implemented within BIOS or other system software. Along these lines, power management may be performed in concert with other power control units implemented autonomously or semi-autonomously, e.g., as controllers or executing software in cores, clusters, IP blocks and/or in other parts of the overall system.

Various I/O devices 814 may be coupled to first interface 816, along with a bus bridge 818 which couples first interface 816 to a second interface 820. In some examples, one or more additional processor(s) 815, such as coprocessors, high throughput many integrated core (MIC) processors, GPGPUs, accelerators (such as graphics accelerators or digital signal processing (DSP) units), field programmable gate arrays (FPGAs), or any other processor, are coupled to first interface 816. In some examples, second interface 820 may be a low pin count (LPC) interface. Various devices may be coupled to second interface 820 including, for example, a keyboard and/or mouse 822, communication devices 827 and storage circuitry 828. Storage circuitry 828 may be one or more non-transitory machine-readable storage media as described below, such as a disk drive or other mass storage device which may include instructions/code and data 830 and may implement the storage in some examples. Further, an audio I/O 824 may be coupled to second interface 820. Note that other architectures than the point-to-point architecture described above are possible. For example, instead of the point-to-point architecture, a system such as multiprocessor system 800 may implement a multi-drop interface or other such architecture.

Processor cores may be implemented in different ways, for different purposes, and in different processors. For instance, implementations of such cores may include: 1) a general purpose in-order core intended for general-purpose computing; 2) a high-performance general purpose out-of-order core intended for general-purpose computing; 3) a special purpose core intended primarily for graphics and/or scientific (throughput) computing. Implementations of different processors may include: 1) a CPU including one or more general purpose in-order cores intended for general-purpose computing and/or one or more general purpose out-of-order cores intended for general-purpose computing; and 2) a coprocessor including one or more special purpose cores intended primarily for graphics and/or scientific (throughput) computing. Such different processors lead to different computer system architectures, which may include: 1) the coprocessor on a separate chip from the CPU; 2) the coprocessor on a separate die in the same package as a CPU; 3) the coprocessor on the same die as a CPU (in which case, such a coprocessor is sometimes referred to as special purpose logic, such as integrated graphics and/or scientific (throughput) logic, or as special purpose cores); and 4) a system on a chip (SoC) that may be included on the same die as the described CPU (sometimes referred to as the application core(s) or application processor(s)), the above described coprocessor, and additional functionality. Example core architectures are described next, followed by descriptions of example processors and computer architectures.

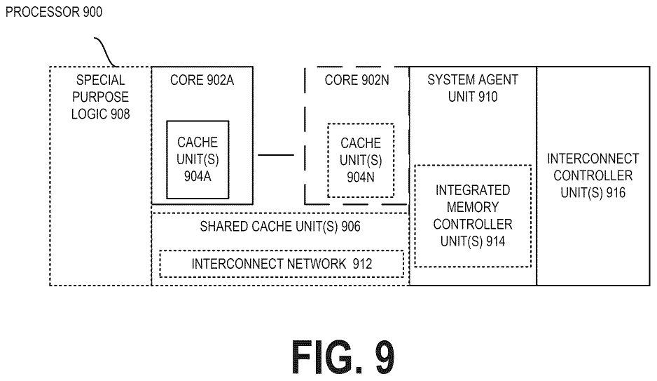

FIG. 9 illustrates a block diagram of an example processor and/or SoC 900 that may have one or more cores and an integrated memory controller and may include age monitor and/or voltage adjustment circuits in accordance with some embodiments. The solid lined boxes illustrate a processor and/or SoC 900 with a single core 902(A), system agent unit circuitry 910, and a set of one or more interface controller unit(s) circuitry 916, while the optional addition of the dashed lined boxes illustrates an alternative processor and/or SoC 900 with multiple cores 902(A)-(N), a set of one or more integrated memory controller unit(s) circuitry 914 in the system agent unit circuitry 910, and special purpose logic 908, as well as a set of one or more interface controller unit(s) circuitry 916. Note that the processor and/or SoC 900 may be one of the processors 870 or 880, or co-processor 838 or 815 of FIG. 8.

Thus, different implementations of the processor and/or SoC 900 may include: 1) a CPU with the special purpose logic 908 being a high-throughput processor, a network or communication processor, a compression engine, a graphics processor, a general purpose graphics processing unit (GPGPU), a neural-network processing unit (NPU), an embedded processor, a security processor, a matrix accelerator, an in-memory analytics accelerator, a compression accelerator, a data streaming accelerator, data graph operations, or the like (which may include one or more cores, not shown), and the cores 902(A)-(N) being one or more general purpose cores (e.g., general purpose in-order cores, general purpose out-of-order cores, or a combination of the two); 2) a co-processor with the cores 902(A)-(N) being a large number of special purpose cores intended primarily for graphics and/or scientific (throughput); and 3) a co-processor with the cores 902(A)-(N) being a large number of general purpose in-order cores. Thus, the processor and/or SoC 900 may be a general-purpose processor, co-processor or special-purpose processor, such as, for example, a network or communication processor, compression engine, graphics processor, GPGPU (general purpose graphics processing unit), a high throughput many integrated core (MIC) co-processor (including 30 or more cores), embedded processor, or the like. The processor may be implemented on one or more chips. The processor and/or SoC 900 may be a part of and/or may be implemented on one or more substrates using any of a number of process technologies, such as, for example, complementary metal oxide semiconductor (CMOS), bipolar CMOS (BiCMOS), P-type metal oxide semiconductor (PMOS), or N-type metal oxide semiconductor (NMOS).

A memory hierarchy includes one or more levels of cache unit(s) circuitry 904(A)-(N) within the cores 902(A)-(N), a set of one or more shared cache unit(s) circuitry 906, and external memory (not shown) coupled to the set of integrated memory controller unit(s) circuitry 914. The set of one or more shared cache unit(s) circuitry 906 may include one or more mid-level caches, such as level 2 (L2), level 3 (L3), level 4 (L4), or other levels of cache, such as a last level cache (LLC), and/or combinations thereof. While in some examples interface network circuitry 912 (e.g., a ring interconnect) interfaces the special purpose logic 908 (e.g., integrated graphics logic), the set of shared cache unit(s) circuitry 906, and the system agent unit circuitry 910, alternative examples use any number of well-known techniques for interfacing such units. In some examples, coherency is maintained between one or more of the shared cache unit(s) circuitry 906 and cores 902(A)-(N). In some examples, interface controller unit(s) circuitry 916 couple the cores 902(A)-(N) to one or more other devices 918 such as one or more I/O devices, storage, one or more communication devices (e.g., wireless networking, wired networking, etc.), etc.

In some examples, one or more of the cores 902(A)-(N) are capable of multi-threading. The system agent unit circuitry 910 includes those components coordinating and operating cores 902(A)-(N). The system agent unit circuitry 910 may include, for example, power control unit (PCU) circuitry and/or display unit circuitry (not shown). The PCU may be or may include logic and components needed for regulating the power state of the cores 902(A)-(N) and/or the special purpose logic 908 (e.g., integrated graphics logic). The display unit circuitry is for driving one or more externally connected displays.

The cores 902(A)-(N) may be homogenous in terms of instruction set architecture (ISA). Alternatively, the cores 902(A)-(N) may be heterogeneous in terms of ISA; that is, a subset of the cores 902(A)-(N) may be capable of executing an ISA, while other cores may be capable of executing only a subset of that ISA or another ISA.

### BPC—System w/ PP

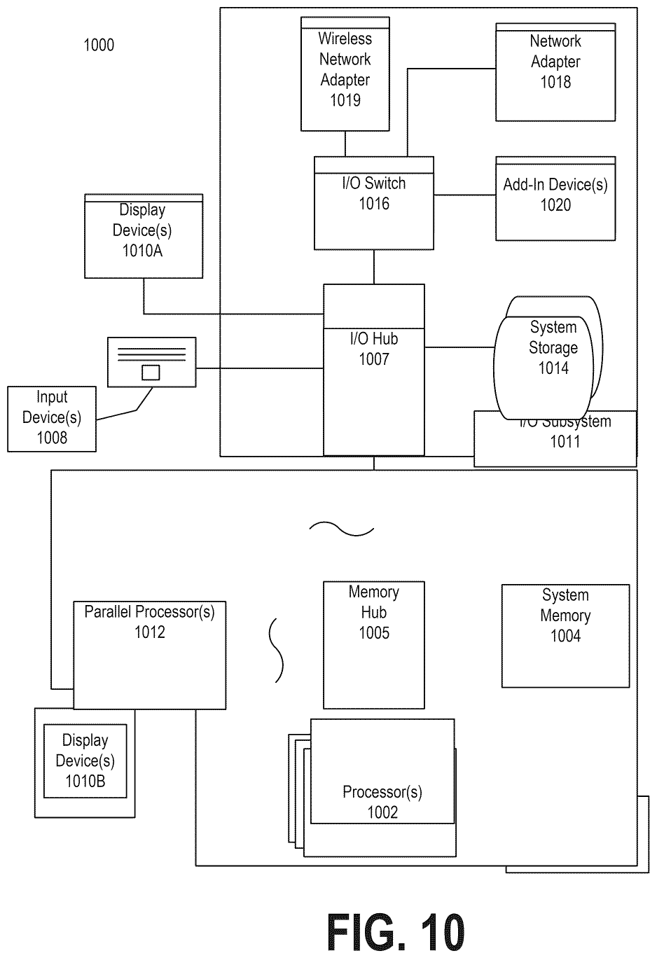

FIG. 10 is a block diagram illustrating a computing system 1000 configured to implement one or more aspects of the examples described herein. The computing system 1000 includes a processing subsystem 1001 having one or more processor(s) 1002 and a system memory 1004 communicating via an interconnection path that may include a memory hub 1005. The memory hub 1005 may be a separate component within a chipset component or may be integrated within the one or more processor(s) 1002. The memory hub 1005 couples with an I/O subsystem 1011 via a communication link 1006. The I/O subsystem 1011 includes an I/O hub 1007 that can enable the computing system 1000 to receive input from one or more input device(s) 1008. Additionally, the I/O hub 1007 can enable a display controller, which may be included in the one or more processor(s) 1002, to provide outputs to one or more display device(s) 1010A. In some examples the one or more display device(s) 1010A coupled with the I/O hub 1007 can include a local, internal, or embedded display device.

The processing subsystem 1001, for example, includes one or more parallel processor(s) 1012 coupled to memory hub 1005 via a bus or communication link 1013. The communication link 1013 may be one of any number of standards-based communication link technologies or protocols, such as, but not limited to PCI Express, or may be a vendor specific communications interface or communications fabric. The one or more parallel processor(s) 1012 may form a computationally focused parallel or vector processing system that can include a large number of processing cores and/or processing clusters, such as a many integrated core (MIC) processor. For example, the one or more parallel processor(s) 1012 form a graphics processing subsystem that can output pixels to one of the one or more display device(s) 1010A coupled via the I/O hub 1007. The one or more parallel processor(s) 1012 can also include a display controller and display interface (not shown) to enable a direct connection to one or more display device(s) 1010B.

Within the I/O subsystem 1011, a system storage unit 1014 can connect to the I/O hub 1007 to provide a storage mechanism for the computing system 1000. An I/O switch 1016 can be used to provide an interface mechanism to enable connections between the I/O hub 1007 and other components, such as a network adapter 1018 and/or wireless network adapter 1019 that may be integrated into the platform, and various other devices that can be added via one or more add-in device(s) 1020. The add-in device(s) 1020 may also include, for example, one or more external graphics processor devices, graphics cards, and/or compute accelerators. The network adapter 1018 can be an Ethernet adapter or another wired network adapter. The wireless network adapter 1019 can include one or more of a Wi-Fi, Bluetooth, near field communication (NFC), or other network device that includes one or more wireless radios.

The computing system 1000 can include other components not explicitly shown, including USB or other port connections, optical storage drives, video capture devices, and the like, which may also be connected to the I/O hub 1007. Communication paths interconnecting the various components in FIG. 10 may be implemented using any suitable protocols, such as PCI (Peripheral Component Interconnect) based protocols (e.g., PCI-Express), or any other bus or point-to-point communication interfaces and/or protocol(s), such as the NVLink high-speed interconnect, Compute Express Link™ (CXL™) (e.g., CXL.mem), Infinity Fabric (IF), Ethernet (IEEE 802.3), remote direct memory access (RDMA), InfiniBand, Internet Wide Area RDMA Protocol (iWARP), Transmission Control Protocol (TCP), User Datagram Protocol (UDP), quick UDP Internet Connections (QUIC), RDMA over Converged Ethernet (ROCE), Intel QuickPath Interconnect (QPI), Intel Ultra Path Interconnect (UPI), Intel On-Chip System Fabric (IOSF), Omnipath, HyperTransport, Advanced Microcontroller Bus Architecture (AMBA) interconnect, OpenCAPI, Gen-Z, Cache Coherent Interconnect for Accelerators (CCIX), 3GPP Long Term Evolution (LTE) (4G), 3GPP 5G, and variations thereof, or wired or wireless interconnect protocols known in the art. In some examples, data can be copied or stored to virtualized storage nodes using a protocol such as non-volatile memory express (NVMe) over Fabrics (NVMe-oF) or NVMe.

The one or more parallel processor(s) 1012 may incorporate circuitry optimized for graphics and video processing, including, for example, video output circuitry, and constitutes a graphics processing unit (GPU). Alternatively or additionally, the one or more parallel processor(s) 1012 can incorporate circuitry optimized for general purpose processing, while preserving the underlying computational architecture, described in greater detail herein. Components of the computing system 1000 may be integrated with one or more other system elements on a single integrated circuit. For example, the one or more parallel processor(s) 1012, memory hub 1005, processor(s) 1002, and I/O hub 1007 can be integrated into a system on chip (SoC) integrated circuit. Alternatively, the components of the computing system 1000 can be integrated into a single package to form a system in package (SIP) configuration. In some examples at least a portion of the components of the computing system 1000 can be integrated into a multi-chip module (MCM), which can be interconnected with other multi-chip modules into a modular computing system.

It will be appreciated that the computing system 1000 shown herein is illustrative and that variations and modifications are possible. The connection topology, including the number and arrangement of bridges, the number of processor(s) 1002, and the number of parallel processor(s) 1012, may be modified as desired. For instance, system memory 1004 can be connected to the processor(s) 1002 directly rather than through a bridge, while other devices communicate with system memory 1004 via the memory hub 1005 and the processor(s) 1002. In other alternative topologies, the parallel processor(s) 1012 are connected to the I/O hub 1007 or directly to one of the one or more processor(s) 1002, rather than to the memory hub 1005. In other examples, the I/O hub 1007 and memory hub 1005 may be integrated into a single chip. It is also possible that two or more sets of processor(s) 1002 are attached via multiple sockets, which can couple with two or more instances of the parallel processor(s) 1012.

Some of the particular components shown herein are optional and may not be included in all implementations of the computing system 1000. For example, any number of add-in cards or peripherals may be supported, or some components may be eliminated. Furthermore, some architectures may use different terminology for components similar to those illustrated in FIG. 10. For example, the memory hub 1005 may be referred to as a Northbridge in some architectures, while the I/O hub 1007 may be referred to as a Southbridge.

Illustrative examples of the technologies disclosed herein are provided below. An embodiment of the technologies may include any one or more, and any compatible combination of, the examples described below.

Example 1 is an apparatus that includes a circuit group, a management circuit, a first oscillator and a second oscillator. The circuit group is coupled to a supply voltage node. The first oscillator includes a first supply node that is coupled to the supply voltage node through a switch that is controlled by the management circuit. The second oscillator is coupled with the circuit group to the supply voltage node.

Example 2 includes the subject matter of example 1, and wherein the first and second oscillators are ring oscillators.

Example 3 includes the subject matter of any of examples 1-2, and comprising a first counter coupled to the first oscillator and a second counter coupled to the second oscillator, the first and second counters being controllable by the management circuit.

Example 4 includes the subject matter of any of examples 1-3, and comprising a temperature sensing circuit coupled to the management circuit.

Example 5 includes the subject matter of any of examples 1-4, and wherein the temperature sensing circuit is formed from the first oscillator and a third oscillator that includes a third supply node coupled to the first supply node.

Example 6 includes the subject matter of any of examples 1-5, and wherein the temperature sensing circuit is a digital temperature sensor circuit.

Example 7 includes the subject matter of any of examples 1-6, and wherein the management circuit includes a look-up table with parameters to identify an aging value for the circuit group based on measured frequencies from the first and second oscillators.

Example 8 includes the subject matter of any of examples 1-7, and wherein the management circuit includes a mathematical function to generate an aging value for the circuit group based on measured frequencies from the first and second oscillators.

Example 9 includes the subject matter of any of examples 1-8, and comprising a plurality of processing cores that each include the first and second oscillators to determine an aging value for the core.

Example 10 includes the subject matter of any of examples 1-9, and wherein the first and second oscillators are formed using the same circuit designs and include more than 20 sequentially coupled inverters.

Example 11 is an apparatus that includes a circuit group, a management circuit, a first oscillator, and second oscillator, and a multiplexer switch. The circuit group is coupled to a supply voltage node. The first oscillator includes a first supply node that is coupled to the supply voltage node through a power gate that is controlled by the management circuit. The second oscillator includes a second supply node. The multiplexing switch includes: (i) a multiplexing switch output node coupled to the second supply node, (ii) a first multiplexing switch input coupled to the supply voltage node, and (iii) a second multiplexing switch input coupled to a variable voltage source that is controllable by the management circuit.

Example 12 includes the subject matter of example 11, and wherein the first and second oscillators are ring oscillators.

Example 13 includes the subject matter of any of examples 11-12, and comprising a first counter coupled to the first oscillator and a second counter coupled to the second oscillator, the first and second counters being controllable by the management circuit.

Example 14 includes the subject matter of any of examples 11-13, and wherein the management circuit has logic to increase the variable voltage source until a frequency of the second oscillator is greater or equal to a frequency of the first oscillator.

Example 15 includes the subject matter of any of examples 11-14, and wherein the logic is to adjust a voltage/frequency operating point for the circuit group based on an amount of increased voltage by the variable voltage source.

Example 16 includes the subject matter of any of examples 11-15, and comprising a plurality of processing cores that each include the first and second oscillators to determine an operating point voltage increase for the core.

Example 17 is a non-transitory computer readable storage medium having instructions that when executed perform a method. The method includes measuring a first frequency from a first oscillator. It also includes measuring a second frequency from a second oscillator that is configured the same as the first oscillator, the second oscillator being powered along with a circuit group that is to be monitored. It also includes removing power from the first oscillator when the first frequency is not being measured. It also includes determining an aging value for the circuit group based on the first and second frequencies.

Example 18 includes the subject matter of example 17, and comprising identifying a temperature and a voltage for the first and second oscillators when the first and second frequencies are measured.

Example 19 includes the subject matter of any of examples 17-18, and wherein the temperature is identified using a third oscillator with transistors having different voltage thresholds than those for the first oscillator.

Example 20 includes the subject matter of any of examples 17-19, and wherein the voltage is identified using the third oscillator.

Example 21 includes the subject matter of any of examples 17-20, and wherein the voltage is identified from a supply voltage control code.

Example 22 includes the subject matter of any of examples 17-21, and wherein the temperature is identified using a temperature sensor.

Example 23 is a system including a processor with the storage medium including the subject matter of any of examples 17-22, and it also includes a memory coupled to the processor.

Reference in the specification to “an embodiment,” “one embodiment,” “some embodiments,” or “other embodiments” means that a particular feature, structure, or characteristic described in connection with the embodiments is included in at least some embodiments, but not necessarily all embodiments. The various appearances of “an embodiment,” “one embodiment,” or “some embodiments” are not necessarily all referring to the same embodiments. If the specification states a component, feature, structure, or characteristic “may,” “might,” or “could” be included, that particular component, feature, structure, or characteristic is not required to be included.

Throughout the specification, and in the claims, the term “connected” means a direct connection, such as electrical, mechanical, or magnetic connection between the things that are connected, without any intermediary devices.

The term “coupled” means a direct or indirect connection, such as a direct electrical, mechanical, or magnetic connection between the things that are connected or an indirect connection, through one or more passive or active intermediary devices.

The term “circuit” or “module” may refer to one or more passive and/or active components that are arranged to cooperate with one another to provide a desired function. It should be appreciated that different circuits or modules may consist of separate components, they may include both distinct and shared components, or they may consist of the same components. For example, A controller circuit may be a first circuit for performing a first function, and at the same time, it may be a second controller circuit for performing a second function, related or not related to the first function.

The meaning of “in” includes “in” and “on” unless expressly distinguished for a specific description.

The terms “substantially,” “close,” “approximately,” “near,” and “about,” unless otherwise indicated, generally refer to being within +/−10% of a target value.

Unless otherwise specified, the use of the ordinal adjectives “first,” “second,” and “third,” etc., to describe a common object, merely indicate that different instances of like objects are being referred to and are not intended to imply that the objects so described must be in a given sequence, either temporally, spatially, in ranking or in any other manner

For the purposes of the present disclosure, phrases “A and/or B” and “A or B” mean (A), (B), or (A and B). For the purposes of the present disclosure, the phrase “A, B, and/or C” means (A), (B), (C), (A and B), (A and C), (B and C), or (A, B and C).

It is pointed out that those elements of the figures having the same reference numbers (or names) as the elements of any other figure can operate or function in any manner similar to that described but are not limited to such.

For purposes of the embodiments, unless expressly described differently, the transistors in various circuits and logic blocks described herein may be implemented with any suitable transistor type such as field effect transistors (FETs) or bipolar type transistors. FET transistor types may include but are not limited to metal oxide semiconductor (MOS) type FETs such as tri-gate, FinFET, and gate all around (GAA) FET transistors, as well as tunneling FET (TFET) transistors, ferroelectric FET (FeFET) transistors.

In the drawings of the embodiments, signals are represented with lines. Some lines may appear different from others, for example, thicker or hatched, to distinguish from other depicted signals for ease of understanding. Along these lines, some signal lines may have arrows at one or more ends, to indicate a primary direction of information flow. However, such indications are not intended to be limiting. Rather, lines are used in connection with one or more exemplary embodiments in a given figure to facilitate easier understanding of concepts embodied in block, circuit, and/or flow diagrams. Any represented signal, as dictated by design needs or preferences, may actually comprise one or more signals that may travel in either direction and may be implemented with any suitable type of signal scheme, e.g., analog, digital, wired, wireless, upon the platform within which the present disclosure is to be implemented.

As defined herein, the term “computer readable storage medium” means a storage medium that contains or stores program code for use by or in connection with an instruction execution system, apparatus, or device. As defined herein, a “computer readable storage medium” is not a transitory, propagating signal per se. A computer readable storage medium may be, but is not limited to, an electronic storage device, a magnetic storage device, an optical storage device, an electromagnetic storage device, a semiconductor storage device, or any suitable combination of the foregoing. Memory elements, as described herein, are examples of a computer readable storage medium.

As defined herein, the term “processor” means at least one hardware circuit configured to carry out instructions contained in program code. The hardware circuit may be implemented with one or more integrated circuits. Examples of a processor include, but are not limited to, a central processing unit (CPU), an array processor, a vector processor, a digital signal processor (DSP), a field-programmable gate array (FPGA), a programmable logic array (PLA), an application specific integrated circuit (ASIC), programmable logic circuitry, a graphics processing unit (GPU), a controller, and so forth. It should be appreciated that a logical processor, on the other hand, is a processing abstraction associated with a core, for example when one or more SMT cores are being used such that multiple logical processors may be associated with a given core, for example, in the context of core thread assignment.

It should be appreciated that a processor or processor system may be implemented in various different manners. For example, they may be implemented on a single die, multiple dies (dielets, chiplets), one or more dies in a common package, or one or more dies in multiple packages. Along these lines, some of these blocks may be located separately on different dies or together on two or more different dies.

While the flow diagrams in the figures show a particular order of operations performed by certain embodiments, it should be understood that such order is exemplary (e.g., alternative embodiments may perform the operations in a different order, combine certain operations, overlap certain operations, etc.).

While the has been described in terms of several embodiments, those skilled in the art will recognize that the disclosure is not limited to the embodiments described, can be practiced with modification and alteration within the spirit and scope of the appended claims. The description is thus to be regarded as illustrative instead of limiting.

What is claimed is:

1. An apparatus, comprising:
a circuit group coupled to a supply voltage node;
a management circuit;
a first oscillator including a first supply node that is coupled to the supply voltage node through a switch that is controlled by the management circuit; and
a second oscillator that is coupled with the circuit group to the supply voltage node.

2. The apparatus of claim 1, wherein the first and second oscillators are ring oscillators.

3. The apparatus of claim 1, comprising a first counter coupled to the first oscillator and a second counter coupled to the second oscillator, the first and second counters being controllable by the management circuit.

4. The apparatus of claim 1, comprising a temperature sensing circuit coupled to the management circuit.

5. The apparatus of claim 4, wherein the temperature sensing circuit comprising the first oscillator and a third oscillator that includes a third supply node coupled to the first supply node.

6. The apparatus of claim 4, wherein the temperature sensing circuit is a digital temperature sensor circuit.

7. The apparatus of claim 1, wherein the management circuit includes a look-up table with parameters to identify an aging value for the circuit group based on measured frequencies from the first and second oscillators.

8. The apparatus of claim 1, wherein the management circuit includes a mathematical function to generate an aging value for the circuit group based on measured frequencies from the first and second oscillators.

9. The apparatus of claim 1, comprising a plurality of processing cores that each include the first and second oscillators to determine an aging value for the core.

10. The apparatus of claim 1, wherein the first and second oscillators conform to the same circuit design and include more than 20 sequentially coupled inverters.

11. An apparatus, comprising:
a circuit group coupled to a supply voltage node;
a management circuit;
a first oscillator including a first supply node that is coupled to the supply voltage node through a power gate that is coupled to the management circuit;
a second oscillator including a second supply node; and
a multiplexing switch including: (i) a multiplexing switch output node coupled to the second supply node, (ii) a first multiplexing switch input coupled to the supply voltage node, and (iii) a second multiplexing switch input coupled to a variable voltage source that is controllable by the management circuit.

12. The apparatus of claim 11, wherein the first and second oscillators are ring oscillators.

13. The apparatus of claim 11, comprising a first counter coupled to the first oscillator and a second counter coupled to the second oscillator, the first and second counters being controllable by the management circuit.

14. The apparatus of claim 11, wherein the management circuit is capable of increasing the variable voltage source until a frequency of the second oscillator is greater or equal to a frequency of the first oscillator.

15. The apparatus of claim 14, wherein the management circuit is capable of adjusting a voltage/frequency operating point for the circuit group based on an amount of increased voltage by the variable voltage source.

16. The apparatus of claim 11, comprising a plurality of processing cores that include the first and second oscillators to determine an operating point voltage increase for the core.

17. A non-transitory computer readable storage medium having instructions that when executed cause a processor to:
measure a first frequency from a first oscillator;
measure a second frequency from a second oscillator that is configured the same as the first oscillator, the second oscillator being powered along with a monitored circuit group; removing power from the first oscillator when the first frequency is not being measured; and
determine an aging value for the circuit group based on the first and second frequencies.

18. The storage medium of claim 17, comprising identifying a temperature and a voltage for the first and second oscillators when the first and second frequencies are measured.

19. The storage medium of claim 18, wherein the temperature is identified using a third oscillator with transistors having different voltage thresholds than those for the first oscillator.

20. A system including a processor with the storage medium as recited in claim 17 and a memory coupled to the processor.
